(19) United States
(12) Patent Application Publication
(10) Pub. No.: US 2016/0138161 A1
(43) Pub. Date: May 19, 2016

(54) RADICAL ASSISTED CURE OF DIELECTRIC FILMS

(71) Applicant: Applied Materials, Inc., Santa Clara, CA (US)

(72) Inventors: Yihong CHEN, San Jose, CA (US); Shaunak MUKHERJEE, Santa Clara, CA (US); Kelvin CHAN, San Ramon, CA (US); Abhijit Basu MALLICK, Fremont, CA (US)

(21) Appl. No.: 14/815,283

(22) Filed: Jul. 31, 2015

Related U.S. Application Data
(60) Provisional application No. 62/081,794, filed on Nov. 19, 2014.

(51) Int. Cl. C23C 16/505; H01J 37/32; C09D 1/00

(52) U.S. Cl. CPC C23C 16/505; C09D 1/00; H01J 37/32357; H01J 37/3244; H01J 2237/338

(57) ABSTRACT

Embodiments described herein generally relate to apparatus and methods for reducing hydrogen content of a film. Apparatus may include a chamber body, a support member coupled to a lift mechanism, and a source of hydrogen radicals. The chamber may have a radical conduit coupled with the source of hydrogen radicals at a first end and coupled with the chamber body at a second end. The chamber may have a dual-channel showerhead coupled with a lid rim. The dual-channel showerhead may be disposed between the radical source and the support member. The showerhead may face the support member. Methods may include forming a first film having a hydrogen content of about 1% to about 50% on a substrate in a chamber, and exposing the first film to hydrogen radicals to form a second film having reduced hydrogen content.

### CROSS-REFERENCE TO RELATED APPLICATIONS

This application claims benefit of U.S. Provisional Patent Application No. 62/081,794, filed Nov. 19, 2014, which is incorporated by reference in its entirety.

### FIELD

Embodiments disclosed herein generally relate to forming dielectric films, and more specifically to radical-based deposition of dielectric films.

### BACKGROUND

The formation of hydrogen-free dielectric films, such as hydrogen-free silicon-containing dielectric films, is a process being investigated for developing the next generation of electronics devices. Plasma enhanced chemical vapor deposition (PECVD) is commonly used to form dielectric films. However, current PECVD techniques for depositing amorphous silicon-containing dielectric films result in films containing a high hydrogen content, such as about 15 atomic percent or more of hydrogen. The high hydrogen content is generally in the form of silicon-hydrogen and/or nitrogen-hydrogen bonds, which produce defects in the dielectric films. Moreover, a high hydrogen content results in films with low etch selectivity, low thermal and mechanical performance and properties, and high shrinkage. In addition, plasma based process tends to damage the films due to charged particle bombardment and high energy UV irradiation. Therefore, there is a need for apparatus and methods for forming dielectric films, such as hydrogen-free, or reduced hydrogen content, dielectric films.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this present disclosure and are therefore not to be considered limiting of its scope, for the present disclosure may admit to other equally effective embodiments.

FIG. 1 is a cross sectional view of an apparatus according to one embodiment.

FIG. 2A is a cross-sectional view of a dual-channel showerhead usable in the apparatus in FIG. 1.

FIG. 2B is a top view of the dual-channel showerhead of FIG. 2A.

FIG. 2C is a bottom view of the dual-channel showerhead of FIG. 2A.

FIG. 3 is a cross sectional view of an apparatus according to another embodiment.

FIG. 4 is a cross sectional view of an apparatus according to another embodiment.

FIG. 5 is a process flow diagram illustrating a method according to another embodiment.

FIG. 6a is a graph showing overlapping FTIR spectra illustrating reduction in nitrogen-hydrogen and silicon-hydrogen bonds of a dielectric film processed according to one embodiment.

FIG. 6b illustrates the reduction in hydrogen content of a dielectric film after exposing to hydrogen radicals.

FIG. 6c is a graph illustrating the effect of exposing treatments on the DHF etch rate of a film according to one embodiment.

FIG. 6d is a graph illustrating the effect of exposing treatment on the density of the resulting film according to one embodiment.

FIG. 7 is a graph illustrating the electrical properties of as-deposited and exposed SiN films according to one embodiment.

FIG. 8 is a graph illustrating the electrical properties of as-deposited and exposed SiN films according to one embodiment.

FIG. 9a is a perspective view of a carousel process chamber capable of performing forming and exposing processes according to one embodiment.

FIG. 9b is a schematic bottom view of a portion of a gas/plasma distribution assembly according to one embodiment.

FIG. 9c is a schematic plan view of the gas/plasma distribution assembly according to one embodiment.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

In one embodiment, a method of reducing hydrogen content of a film comprises forming a first film having a hydrogen content of about 1% to about 50% on a substrate in a chamber, and exposing the first film to hydrogen radicals to form a second film having reduced hydrogen content.

In another embodiment, an apparatus for reducing hydrogen content of a film comprises a chamber body, a support member coupled to a lift mechanism, and a source of hydrogen radicals. The chamber may have a radical conduit coupled with the source of hydrogen radicals at a first end and coupled with the chamber body at a second end. The chamber may have a dual-channel showerhead coupled with a lid rim. The dual-channel showerhead may be disposed between the radical source and the support member. The showerhead may face the support member.

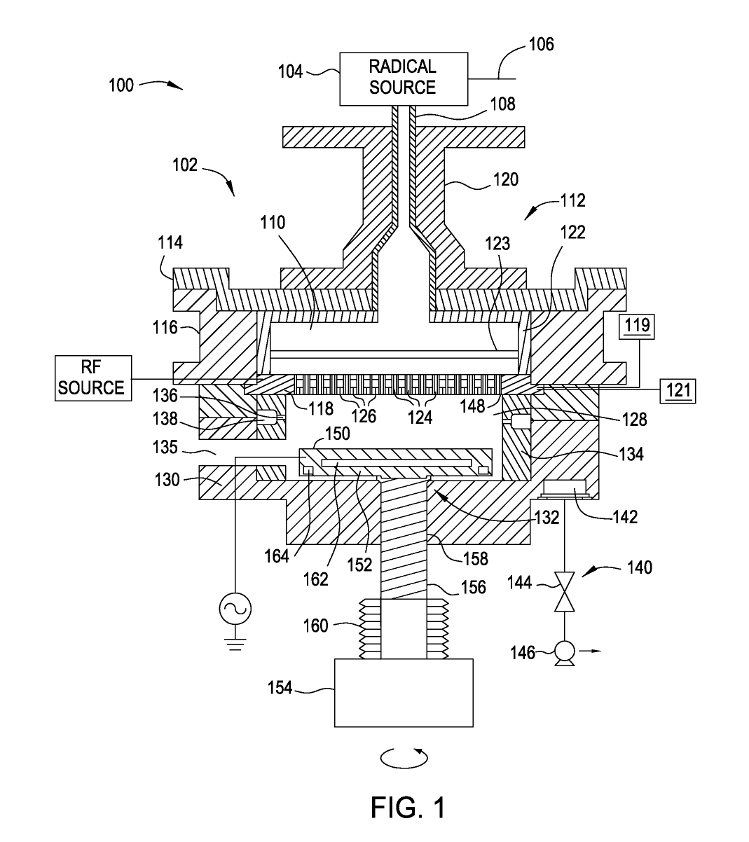

FIG. 1 is a cross sectional view of an apparatus 100 for radical-based forming and exposing of dielectric films according to an embodiment of the present disclosure. As shown in FIG. 1, the apparatus 100 includes a processing chamber 102 comprising a body 130 and a radical source 104 coupled to the body 130. The radical source 104 may be any suitable source that is capable of generating radicals. Radical based CVD has the advantages of well controlled growth conditions and low thermal budget, and produces defect-free, high quality films. The radical source 104 may be a remote plasma source, such as a radio frequency (RF) or very high radio frequency (VHRF) capacitively coupled plasma (CCP) source, an inductively coupled plasma (ICP) source, a microwave induced (MW) plasma source, a DC glow discharge source, an electron cyclotron resonance (ECR) chamber, or a high density plasma (HDP) chamber. Alternatively, the radical source 104 may be an ultraviolet (UV) source or the filament of a hot wire chemical vapor deposition (HW-CVD) chamber. The radical source 104 may include one or more gas inlets 106 and the radical source 104 may be coupled to the processing chamber 102 by a radical conduit 108. One or more process gases, which may be radical-forming gases, and which may be a gas mixture, may enter the radical source 104 via the one or more gas inlets 106. The one or more process gases may comprise a hydrogen containing gas, such as hydrogen, H₂O, and/or ammonia. The one or more process gases may comprise oxygen and/or argon. Radicals generated in the radical source 104, such as hydrogen radicals, travel into the processing chamber 102 through the radical conduit 108.

The radical conduit 108 is a part of a lid assembly 112, which also includes a radical cavity 110, a top plate 114, a lid rim 116, and a dual-channel showerhead 118. The radical conduit 108 may comprise a material that is substantially unreactive to radicals. For example, radical conduit 108 may comprise AlN, SiO₂, Y₂O₃, MgO, anodized Al₂O₃, sapphire, ceramic containing one or more of Al₂O₃, sapphire, AlN, Y₂O₃, MgO, or plastic. A representative example of a suitable SiO₂ material is quartz. Alternatively or additionally, radical conduit 108 may have a coating on the surface that contacts the radicals in operation. The coating may also comprise AlN, SiO₂, Y₂O₃, MgO, anodized Al₂O₃, sapphire, ceramic containing one or more of Al₂O₃, sapphire, AlN, Y₂O₃, MgO, or plastic. If a coating is used, the thickness of the coating may be between about 1 μm and about 1 mm. The coating may be applied using a spray coating process. The radical conduit 108 may be disposed within and supported by a radical conduit support member 120. The radical conduit support member 120 may be disposed on the top plate 114, which rests on the lid rim 116.

The radical cavity 110 is positioned below and coupled to the radical conduit 108, and the radicals generated in the radical source 104 travel to the radical cavity 110 through the radical conduit 108. Radical cavity 110 is defined by the top plate 114 coupled with the lid rim 116 that is coupled with the dual-channel showerhead 118. Optionally, the radical cavity 110 may include a liner 122. The liner 122 may cover surfaces of the top plate 114 and the lid rim 116 that are within the radical cavity 110. The liner 122 may comprise a material that is substantially unreactive to radicals. For example, the liner 122 may comprise AlN, SiO₂, Y₂O₃, MgO, anodized Al₂O₃, sapphire, ceramic containing one or more of Al₂O₃, sapphire, AlN, Y₂O₃, MgO, or plastic. Alternatively or in addition to, the surfaces of the radical cavity 110 that are in contact with radicals may be composed of or coated with a material that is substantially unreactive to radicals. For example, the surfaces may be composed of or coated with AlN, SiO₂, Y₂O₃, MgO, anodized Al₂O₃, sapphire, ceramic containing one or more of Al₂O₃, sapphire, AlN, Y₂O₃, MgO, or plastic. If a coating is used, the thickness of the coating may be between about 1 μm and about 1 mm. By not consuming the generated radicals, the radical flux to a substrate disposed in the processing chamber 102 is increased.

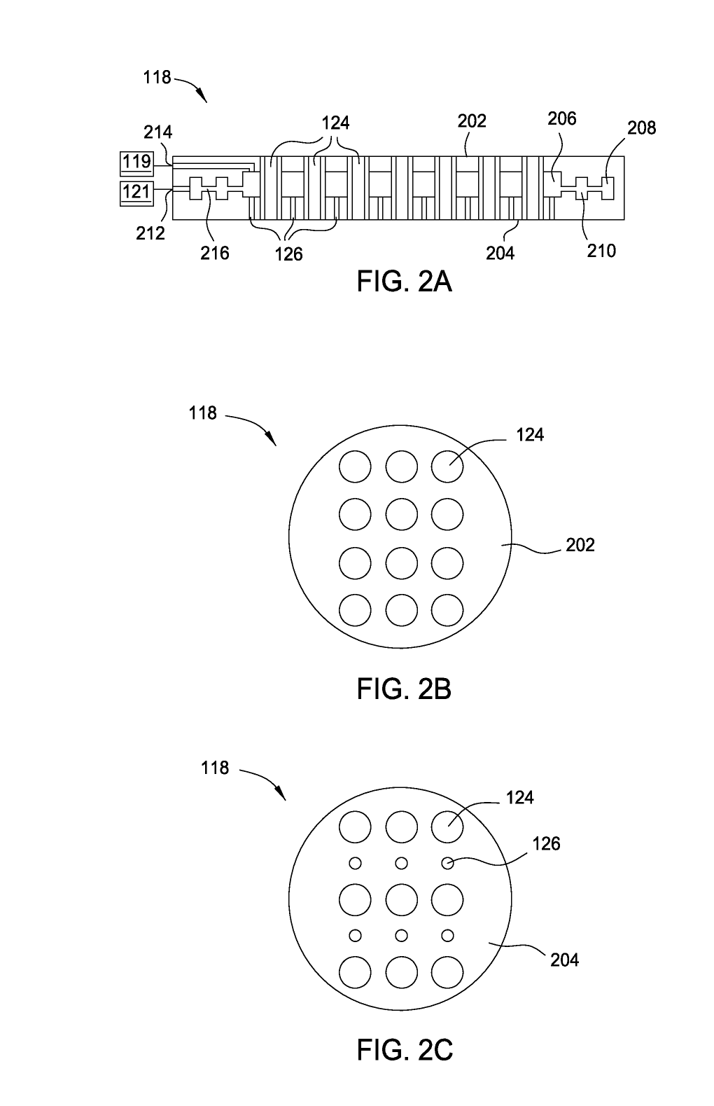

Optionally, a radical distribution plate 123 may be disposed in the radical cavity 110 between the top plate 114 and the dual-channel showerhead 118. The radical distribution plate 123 may be made of the same material as the liner 122. The radical distribution plate 123 may be used to control the radical flow profile. The location of the radical distribution plate 123 in the radical cavity 110, i.e., the distance between the radical distribution plate 123 and the top plate 114, and the distance between the radical distribution plate 123 and the dual-zone showerhead 118, may be adjusted to affect radical distribution. Radicals then pass through a plurality of holes 124 disposed in the dual-channel showerhead 118 to enter into a processing region 128. The dual-channel showerhead 118 further includes a plurality of openings 126 that are smaller in diameter than the plurality of holes 124. The plurality of openings 126 are connected to an internal volume (not shown) that is not in fluid communication with the plurality of holes 124. At least two gas/radical sources 119, 121 may be coupled to the dual-channel showerhead 118. The dual-channel showerhead 118 may be heated or cooled. In one embodiment, the dual-channel showerhead 118 is heated to a temperature of about 100 degrees Celsius to about 250 degrees Celsius. In another embodiment, the dual-channel showerhead 118 is cooled to a temperature of about 25 degrees Celsius to about 75 degrees Celsius. One or more heating elements (not shown) and/or a cooling channel (not shown) may be embedded in the dual-channel showerhead 118. The heating elements and cooling channel may be used to control the temperature of the dual-channel showerhead 118 during operation. The heating elements may be any suitable heating elements, such as one or more resistive heating elements. The heating elements may be connected to one or more power sources (not shown). A coolant may flow through the channel to cool the dual-channel showerhead 118. The dual-channel showerhead 118 is described in more detail below (FIG. 2).

The processing chamber 102 may include the lid assembly 112, a body 130 and a support assembly 132. The support assembly 132 may be at least partially disposed within the body 130. The body 130 may include a slit valve opening 135 to provide access to the interior of the processing chamber 102. The body 130 may include a liner 134 that covers the interior surfaces of the body 130. The liner 134 may include one or more apertures 136 and a pumping channel 138 formed therein that is in fluid communication with a vacuum system 140. The apertures 136 provide a flow path for gases into the pumping channel 138, which provides an egress for the gases within the processing chamber 102. Alternatively, the apertures and the pumping channel may be disposed in the bottom of the body 130, and the gases may be pumped out of the processing chamber 102 from the bottom of the body 130.

The vacuum system 140 may include a vacuum port 142, a valve 144 and a vacuum pump 146. The vacuum pump 146 is in fluid communication with the pumping channel 138 via the vacuum port 142. The apertures 136 allow the pumping channel 138 to be in fluid communication with the processing region 128 within the body 130. The processing region 128 is defined by a lower surface 148 of the dual-channel showerhead 118 and an upper surface 150 of the support assembly 132, and the processing region 128 is surrounded by the liner 134.

The support assembly 132 may include a support member 152 to support a substrate (not shown) for processing within the body 130. The substrate may be any standard size, such as, for example, 300 mm. Alternatively, the substrate may be larger than 300 mm, such as 450 mm or larger. The support member 152 may comprise AlN or aluminum depending on operating temperature. The support member 152 may be configured to chuck the substrate and the support member 152 may be an electrostatic chuck or a vacuum chuck.

The support member 152 may be coupled to a lift mechanism 154 through a shaft 156 which extends through a centrally-located opening 158 formed in a bottom surface of the body 130. The lift mechanism 154 may be flexibly sealed to the body 130 by bellows 160 that prevents vacuum leakage from around the shaft 156. The lift mechanism 154 allows the support member 152 to be moved vertically within the body 130 between a process position and a lower, transfer position. The transfer position is slightly below the opening of the slit valve 135. During operation, the spacing between the substrate and the dual-channel showerhead 118 may be minimized in order to maximize radical flux at the substrate surface. For example, the spacing may be between about 100 mm and about 5,000 mm. The lift mechanism 154 may be configured to rotate the shaft 156 via a rotor coupled to the support member 152, which in turn rotates the support member 152, causing the substrate disposed on the support member 152 to be rotated during operation. Rotation of the substrate helps improving deposition/formation uniformity.

One or more heating elements 162 and a cooling channel 164 may be embedded in the support member 152. The heating elements 162 and cooling channel 164 may be used to control the temperature of the substrate during operation. The heating elements 162 may be any suitable heating elements, such as one or more resistive heating elements. The heating elements 162 may be connected to one or more power sources (not shown). The heating elements 162 may be controlled individually to have independent heating and/or cooling control on multi-zone heating or cooling. With the ability to have independent control on multi-zone heating and cooling, the substrate temperature profile can be enhanced under various process conditions. A coolant may flow through the channel 164 to cool the substrate. The support member 152 may further include gas passages extending to the upper surface 150 for flowing a cooling gas to the backside of the substrate.

The chamber 102 may comprise an RF source. An RF source may be coupled to either the dual-channel showerhead 118 or the support member 152. The RF source may be low frequency, high frequency, or very high frequency. In one embodiment, the dual-channel showerhead 118 is coupled to the RF source and the support member 152 is grounded, as shown in FIG. 1. In another embodiment, the dual-channel showerhead 118 is grounded and the support member 152 is coupled to the RF source. In either embodiment, a capacitively coupled plasma may be formed in the processing region 128 between the dual-channel showerhead 118 and the support member 152 during operation. The capacitively coupled plasma formed in the processing region 128 may be in addition to the plasma formed in the radical source when the radical source is a remote plasma source. The support member 152 may be biased with a DC source to increase ion bombardment. Thus, the processing chamber 102 may be a PECVD chamber, and the apparatus 100 is capable to perform a cyclic process (alternating radical based CVD and PECVD).

FIG. 2A is a cross sectional view of the dual-channel showerhead 118 according to embodiments described herein. The dual-channel showerhead 118 may have a first surface 202 that is facing the radical cavity 110 and a second surface 204 opposite the first surface 202. The second surface 204 may be facing the support assembly 132. The first surface 202 may be spaced from the second surface 204 to provide an internal volume 206. The first and second surfaces 202, 204 may be composed of or coated with a material that is substantially unreactive to radicals. For example, the surfaces 202, 204 may be composed of or coated with AlN, SiO₂, Y₂O₃, MgO, anodized Al₂O₃, sapphire, ceramic containing one or more of Al₂O₃, sapphire, AlN, Y₂O₃, MgO, or plastic. If a coating is used, the thickness of the coating may be between about 1 μm and about 1 mm. A plurality of holes 124 may be formed in the dual-channel showerhead 118. The holes 124 may extend from the first surface 202 to the second surface 204, and radicals generated from the radical source 104 may pass through the holes 124 to reach the substrate disposed on the support assembly 132. The internal volume 206 may surround the plurality of holes 124 and one or more annular channels 208, 210 may surround the internal volume 206 and the plurality of holes 124.

The internal volume 206 may be in fluid communication with the one or more annular channels 208, 210. The plurality of openings 126 may extend from the internal volume 206 to the second surface 204. The one or more annular channels 208, 210 may be connected to an inlet 212, which is coupled to the gas source 121. The gas source 121 may provide a precursor gas, such as a silicon containing gas, to the dual-channel showerhead 118, and the precursor gas flows through the one or more annular channels 208, 210 to the internal volume 206, and to the processing region 128 via the plurality of openings 126. Examples of the silicon containing precursor gas include organosilicon, tetraalkyl orthosilicate gases, and disiloxane. Organosilicon gases include gases of organic compounds having at least one carbon-silicon bond. Tetraalkyl orthosilicate gases include gases consisting of four alkyl groups attached to an SiO₄⁴⁻ ion. More particularly, the one or more precursor gases may be (dimethylsilyl)(trimethylsilyl)methane ((Me)₃SiCH₂SiH(Me)₂), hexamethyldisilane ((Me)₃SiSi(Me)₃), trimethylsilane ((Me)₃SiH), tetramethylsilane ((Me)₄Si), tetraethoxysilane ((EtO)₄Si), tetramethoxysilane ((MeO)₄Si), tetrakis-(trimethylsilyl)silane ((Me₃Si)₄Si), (dimethylamino)dimethylsilane ((Me₂N)SiHMe₂)dimethyldiethoxysilane ((EtO)₂Si(Me)₂), dimethyldimethoxysilane ((MeO)₂Si(Me)₂), methyltrimethoxysilane ((MeO)₃Si(Me)), dimethoxytetramethyldisiloxane (((Me)₂Si(OMe))₂O), tris(dimethylamino)silane ((Me₂N)₃SiH), bis(dimethylamino)methylsilane ((Me₂N)₂CH₃SiH), disiloxane ((SiH₃)₂O), and combinations thereof.

The processing conditions and radical generation conditions during forming using processing chamber 100 may be as follows. The temperature of processing chamber 100 may be maintained between about 100° C. and 800° C., such as between about 100° C. and 350° C. The pressure of the processing chamber 100 may be maintained between about 10 mTorr and about 20 Torr, such as between about 0.5 Torr and about 8 Torr. The at least one silicon-containing precursor gas may be introduced into the processing zone 128 at a flow rate ranging from about 0.1 sccm to about 10,000 sccm for a 300 mm substrate. The radical-forming gases may be introduced into the radical source 104 at a flow rate ranging from about 1 sccm to about 50,000 sccm for a 300 mm substrate. If used, the flow rate of the carrier gases may range from about 1 sccm to about 50,000 sccm for a 300 mm substrate. Radicals may be generated by the radical source 104. For example, if the radical source 104 is a capacitively coupled remote plasma source, the radicals may be generated from an RF power of between about 50 W and about 15,000 W for a 300 mm substrate, such as an RF power from about 2,000 W to about 10,000 W.

For the formation of dielectric films, dielectric films may include but are not limited to silicon-containing dielectric films. For example, films may be deposited that are composed of SiC, SiO, SiCN, SiO₂, SiOC, SiOCN, SiON and SiN. The composition of the films depends on the composition of the precursor gases. SiC films may be deposited, for example, by using (dimethylsilyl)(trimethylsilyl)methane, hexamethyldisilane, and/or trimethylsilane. SiO/SiO₂ films may be deposited, for example, by using TEOS and/or disiloxane. SiCN films may be deposited, for example, by using tris(dimethylamino)silane, bis(dimethylamino)methylsilane, and/or (dimethylamino)dimethylsilane. SiOC films may be deposited, for example, by using tris(dimethylamino)silane, bis(dimethylamino)methylsilane, (dimethylamino)dimethylsilane, tris(dimethylamino)silane, bis(dimethylamino)methylsilane, and/or (dimethylamino)dimethylsilane. SiOCN films can be formed, for example, by using tris(dimethylamino)silane, bis(dimethylamino)methylsilane, and/or (dimethylamino)dimethylsilane. SiON films can be formed, for example, by using disiloxane or trisilylamine. SiN films may be deposited, for example, by using trisilylamine (TSA) and/or silane. The resulting films may be amorphous. In some embodiments, the hydrogen content of the as-deposited dielectric film may be from about 1% to about 50%, from about 10% to about 30%, about 15%.

In a representative example of the forming of a dielectric film on a 300 mm substrate using processing chamber 100, trisilylamine (TSA) is introduced into the processing zone 128 at a flow rate of 30 sccm. The radical-forming gases introduced into the radical source 104 include hydrogen and ammonia, which are introduced at flow rates of 5000 sccm and 500 sccm, respectively. Argon is introduced into the radical source 104 as a carrier gas at a flow rate of 5000 sccm. The temperature and pressure of the processing chamber 100 are 200° C. and 1 Torr, respectively. The radical source 104 is a capacitively coupled remote plasma source, and the radicals may be generated from an RF power of 10,000 W. The spacing is 1000 mil. Formation is carried out for 60 seconds, and the resulting dielectric film has a thickness of 1000 Å.

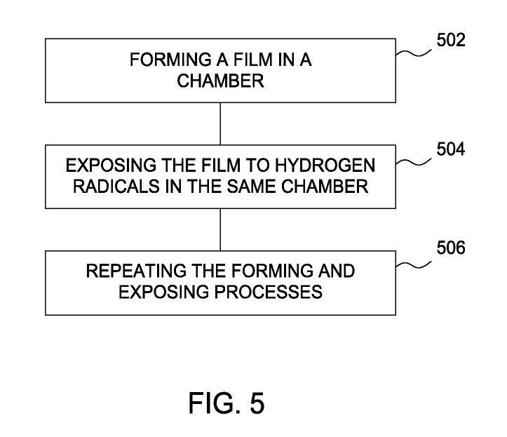

Alternatively, a dielectric film that is about 0.1-100 Å thick may be deposited (for example, in block 502 of FIG. 5). In a representative example of the deposition of a less than 20 Å dielectric film on a 300 mm substrate using processing chamber 100, TSA is introduced into the processing zone 128 at a flow rate of 2 sccm. The radical-forming gases introduced into the radical source 104 include hydrogen and ammonia, which are introduced at flow rates of 1500 sccm and 20 sccm, respectively. Argon is introduced into the radical source 104 as a carrier gas at a flow rate of 5000 sccm. The temperature and pressure of the processing chamber 100 are 350° C. and 6 Torr, respectively. The radical source 104 is a capacitively coupled remote plasma source, and the radicals may be generated from an RF power of 10,000 W. The spacing is 1000 mil. Deposition is carried out for 60 seconds, and the resulting dielectric film has a thickness of about 20 Å.

Since the openings in the plurality of holes 124 are not in fluid communication with the internal volume 206, the radicals passing through the plurality of holes 124 are not mixed with the precursor gas in the dual-channel showerhead 118. Because the showerhead 118 contains one or more channels that are not in fluid communication of each other, the showerhead 118 is a dual-channel showerhead 118. However, showerhead 118 may contain more than two channels which may also be described as a dual-channel showerhead. The plurality of holes 124 each has an inside diameter of about 0.10 in to about 0.35 in. The plurality of openings 126 each has a diameter of about 0.01 in to about 0.04 in.

The one or more annular channels 208, 210 may be connected by one or more connecting channels 216 that have a much smaller cross section than the annular channels 208, 210. This configuration helps the precursor gas to be distributed evenly into the internal volume 206 and out of the openings 126. However, if radicals are to enter the inlet 212, the radicals may recombine when flowing from the large annular channel 208 to the smaller connecting channels 216. In order to provide a path for radicals that are distinct from the radicals formed in the radical source 104, a second inlet 214 is formed in the dual-channel showerhead 118, and the second inlet 214 is connected to the internal volume 206, bypassing the one or more annular channels 208, 210. The second inlet 214 may be distinct from the first inlet 212, and may be configured to direct radicals from the radical source 119 to the internal volume 206 without passing through the one or more annular channels 208, 210. In one embodiment, fluorine radicals are generated in the radical source 119 and are introduced into the internal volume 206 via the second inlet 214. The fluorine radicals are then directed to the processing region 128 through the plurality of openings 126. The fluorine radicals may be used to clean the interior surfaces of the processing chamber 102. The fluorine radicals may not be delivered from the radical source 104 in order to improve the lifetime of the radical source 104.

FIG. 2B is a top view of the dual-channel showerhead 118 according to embodiments described herein. The dual-channel showerhead 118 includes the first surface 202 and the plurality of holes 124 extending from the first surface 202 to the second surface 204. The one or more annular channels 208, 210 and the internal volume 206 are all embedded in the dual-channel showerhead 118, thus are not shown in the top view of the dual-channel showerhead 118.

FIG. 2C is a bottom view of the dual-channel showerhead 118 according to embodiments described herein. The dual-channel showerhead 118 includes the second surface 204, the plurality of holes 124 extending from the first surface 202 to the second surface 204, and the plurality of openings 126. The one or more annular channels 208, 210 and the internal volume 206 are all embedded in the dual-channel showerhead 118, thus are not shown in the bottom view of the dual-channel showerhead 118. The arrangement of the plurality of holes 124 and the plurality of openings 126 may enhance the uniformity of gas/radical distribution across the substrate and may vary based on the process conditions.

Deposition of a film, such as a dielectric film, forms a film comprising hydrogen content, often 15% or more of the overall composition of the deposited film. For a deposited dielectric film, the high hydrogen content is largely in the form of silicon-hydrogen and/or nitrogen-hydrogen bonds. Exposing (for example, block 504 of FIG. 5) after the formation of a film reduces hydrogen content of the film.

Deposition of a dielectric film may be followed by purging processing chamber 102 with, for example, argon and/or hydrogen gas (non-radical hydrogen) that may be supplied from gas inlet 106, gas/radical source 119, gas/radical source 121, or any other gas source into chamber 102. Exposing may then be performed with hydrogen radicals delivered from remote plasma source 104. For a deposited dielectric film during a hydrogen radical exposing process, the hydrogen radicals delivered to the film abstract hydrogen atoms from silicon-hydrogen and/or nitrogen-hydrogen bonds of the dielectric film. The resultant hydrogen gas and excess hydrogen radicals may then be removed from, for example, processing chamber 102 via vacuum system 140. During an exposing process, the radical species remaining in the exposed film combine to form a film with reduced hydrogen content. For example, the exposed film may comprise a decreased amount of silicon-hydrogen and nitrogen-hydrogen bonds along with an increased amount of silicon-nitrogen, silicon-silicon and nitrogen-nitrogen bonds as compared to the as-deposited film before hydrogen radical exposure. Processing chamber 102 may then be purged with, for example, argon and/or hydrogen and a second deposition process may then be performed. A second exposing process may then be performed. Repeating a forming, purge, exposing, purge, forming, purge, exposing process (for example, block 506 of FIG. 5) allows formation of a film of a desired thickness with reduced hydrogen content throughout the film. Furthermore, forming and exposing may be performed within the same chamber which may improve overall process throughput.

The process conditions during exposing using processing chamber 100 may be as follows. The temperature of processing chamber 100 may be maintained between about 100° C. and 800° C., such as between about 100° C. and 350° C. The pressure of the processing chamber 100 may be maintained between about 10 mTorr and about 20 Torr, such as between about 0.8 Torr and about 6 Torr. An at least one exposing gas, such as hydrogen, may be introduced into radical cavity 110 at a flow rate ranging from about 20 sccm to about 8,000 sccm for a 300 mm substrate. If used, the flow rate of one or more carrier gases may range from about 3,000 sccm to about 10,000 sccm for a 300 mm substrate. Radicals may be generated by the radical source 104. For example, if the radical source 104 is a capacitively coupled remote plasma source, the radicals may be generated from an RF power of between about 50 W and about 10,000 W for a 300 mm substrate, such as an RF power from about 50 W to about 500 W.

In a representative example of the exposing of a dielectric film on a 300 mm substrate using processing chamber 100, hydrogen is introduced into the radical source 104 and subsequently to radical cavity 110 at a flow rate of 1500 sccm. Optionally, argon is introduced into the radical cavity at a flow rate of 5000 sccm. The temperature and pressure of the processing chamber 100 are 350° C. and 0.8 Torr, respectively. The spacing is 1000 mil. Exposing is carried out for 120 seconds, and the resulting dielectric film has reduced hydrogen-content as compared to the as-deposited film.

In another embodiment, a material containing silicon-hydrogen, carbon-hydrogen, and/or nitrogen-hydrogen bonds is placed inside a processing chamber, such as processing chamber 100. Thereafter, the material may be exposed to radicals, such as hydrogen radicals, generated substantially as described above, in order to reduce the amount of silicon-hydrogen, carbon-hydrogen, and nitrogen-hydrogen bonds in the film.

The process conditions during purging of chamber 102 of processing chamber 100 may be as follows. The temperature of processing chamber 100 may be maintained between about ambient temperature and 800° C., such as between about 100° C. and 350° C. The pressure of the processing chamber 100 may be maintained between about 10 mTorr and about 20 Torr, such as between about 0.8 Torr and about 6 Torr. An at least one purging gas, such as argon and/or hydrogen gas, may be introduced into chamber 102 at a flow rate ranging from about 20 sccm to about 10,000 sccm.

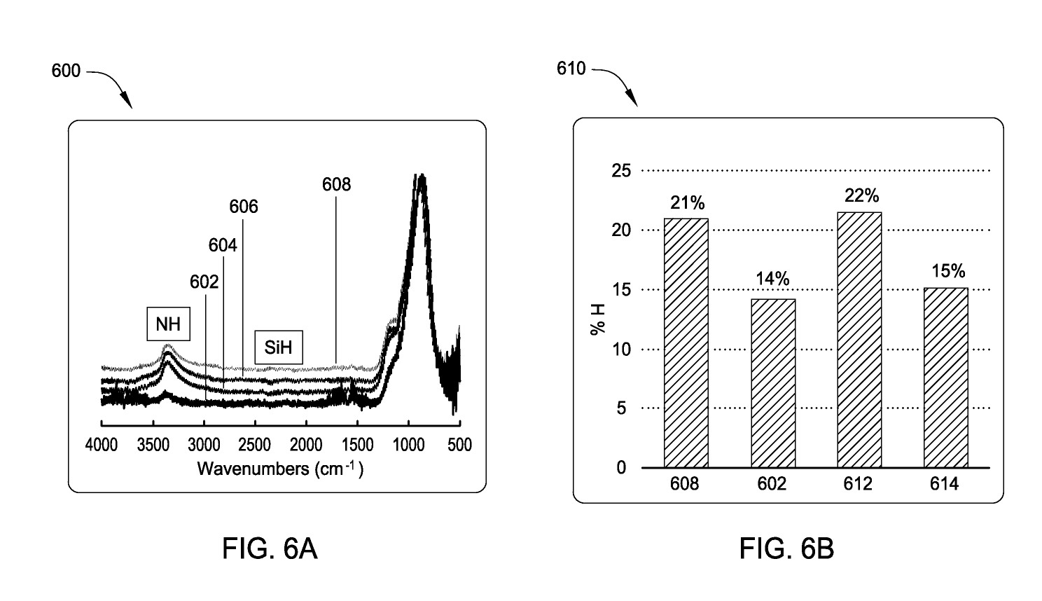

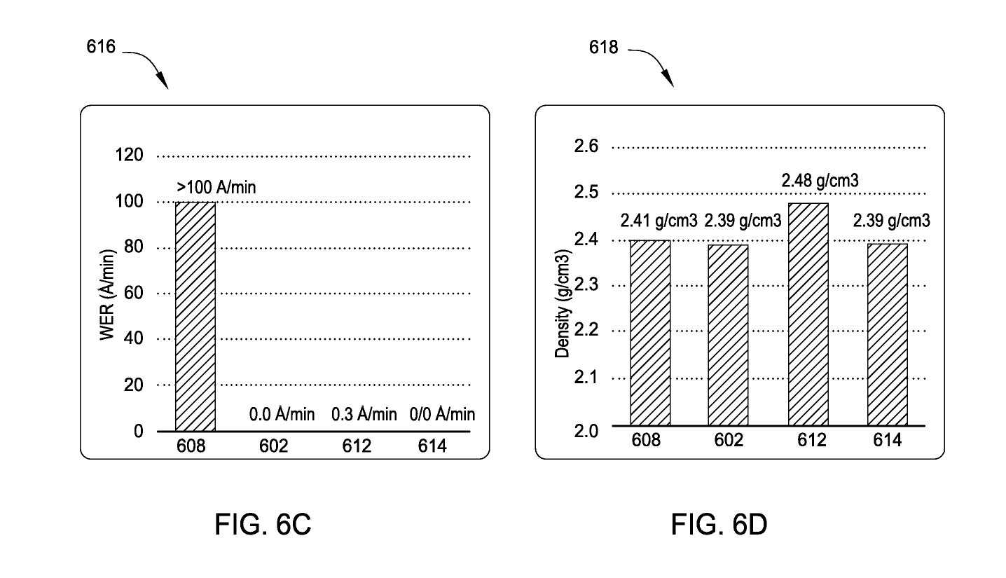

FIG. 6a illustrates overlapping FTIR spectra illustrating reduction in nitrogen-hydrogen (N—H) and silicon-hydrogen (Si—H) bonds of a dielectric film exposed to hydrogen radicals via a remote plasma system (as described above) as compared to N—H and Si—H bonds of an as-deposited film. As shown in FIG. 6a (graph 600), an as-deposited SiN dielectric film 608 from TSA precursor comprises detectable quantities of N—H and Si—H bonds as shown by peaks at about 3400 nm and about 2300 nm, respectively. Radical exposing by a remote plasma system comprising ammonia gas produces a dielectric film with reduced hydrogen content, shown graphically by line 606. Radical exposing by a remote plasma system comprising nitrogen gas also produces a dielectric film with reduced hydrogen content, shown graphically by line 604. Radical exposure by a remote plasma system comprising hydrogen produces a dielectric film with substantially lower content of N—H bonds, shown graphically by line 602. FIG. 6b further illustrates the reduction in hydrogen content of a dielectric film after exposing to hydrogen radicals in a remote plasma system. As shown in FIG. 6b (graph 610), based on the FTIR spectra of FIG. 6a, hydrogen content of an as-deposited SiN film may be reduced from 21% to 14% after exposing a film to hydrogen radicals from a remote plasma source (bar 602), such as radical source 104. PECVD treatment with H₂ radicals, i.e. H₂ radicals formed in-situ, does not significantly reduce hydrogen content of a SiN film (bar 612). However, PECVD treatment with argon reduces hydrogen content of an as-deposited SiN film from 21% to 15%, as shown by bars 608 and 614, respectively.

FIG. 6c illustrates the effect of exposure treatments on the etch rate of the resulting film using diluted hydrofluoric acid (DHF). As shown in FIG. 6c (graph 616), the DHF etch rate of a SiN film (bar 608) may be reduced by remote plasma treatment with H₂ radicals (bar 602), PECVD treatment with H₂ radicals (bar 612), and PECVD treatment with argon (bar 614). FIG. 6d illustrates the effect of exposure treatments on the density of the resulting film. As shown in FIG. 6d (graph 618), the density of a deposited SiN film (bar 608) is not substantially affected by remote plasma treatment with H₂ radicals (bar 602), PECVD treatment with H₂ radicals (bar 612), or PECVD treatment with argon (bar 614).

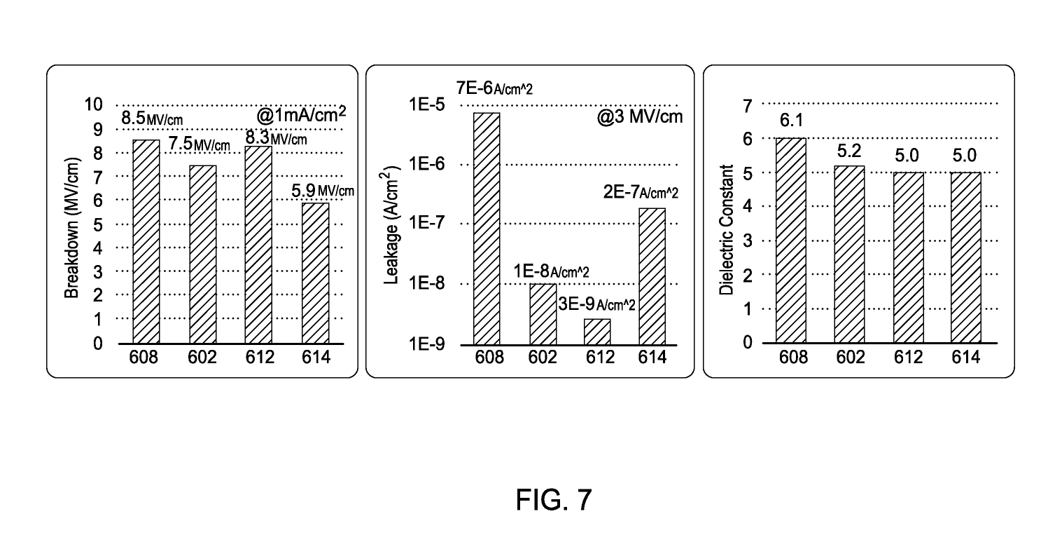

FIG. 7 illustrates the electrical properties of as-deposited and exposed SiN films. As shown in FIG. 7, hydrogen radical exposure only slightly affects breakdown regardless of whether the hydrogen radical exposure occurs via remote plasma system or direct PECVD (bars 602 and 612, respectively) as compared to an as-deposited SiN film (bar 608). However, PECVD treatment with argon degrades the breakdown field of a SiN film (bar 614). Nonetheless, remote plasma treatment with H₂ radicals (bar 602), PECVD treatment with H₂ radicals (bar 612), and PECVD treatment with argon (bar 614) each reduces leakage current and reduces dielectric constant of a SiN film.

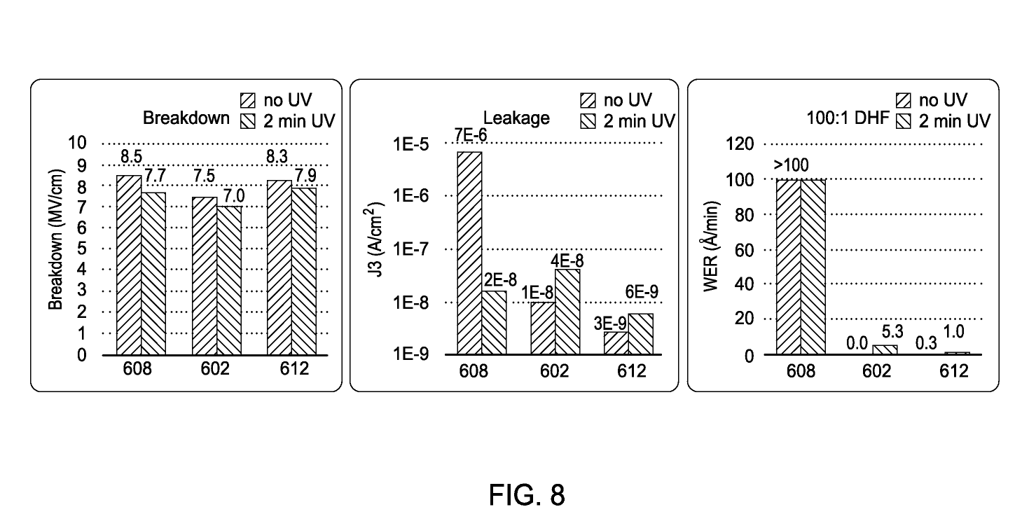

Optionally, an as-deposited or film exposed to hydrogen radicals may be exposed to ultraviolet (UV) curing. FIG. 8 illustrates the electrical properties of as-deposited and hydrogen radical exposed SiN films. As shown in FIG. 8, UV curing alone of an as-deposited SiN film reduces leakage current (J3 (A/cm²)) of the film (bar 608). However, UV curing of a SiN film after remote plasma treatment with H₂ radicals or PECVD treatment with H₂ radicals does not further reduce leakage current (J3 (A/cm²)) of the film (bars 602 and 612, respectively). Furthermore, UV curing does not reduce DHF etch rate (WER (Å/min)) of a SiN film after remote plasma treatment with H₂ radicals (602), after PECVD treatment with H₂ radicals (612), or as-deposited (bar 608).

It is envisioned that hydrogen content may be reduced utilizing apparatus and methods described herein for any deposited film, not merely dielectric films described herein. Furthermore, any supply gas capable of forming hydrogen radicals may be utilized for apparatus and methods described herein. Furthermore, other atomic radicals besides hydrogen radicals may be used for apparatus and methods described herein. Furthermore, a deposited and/or exposed film may be densified by direct CCP with, for example, argon.

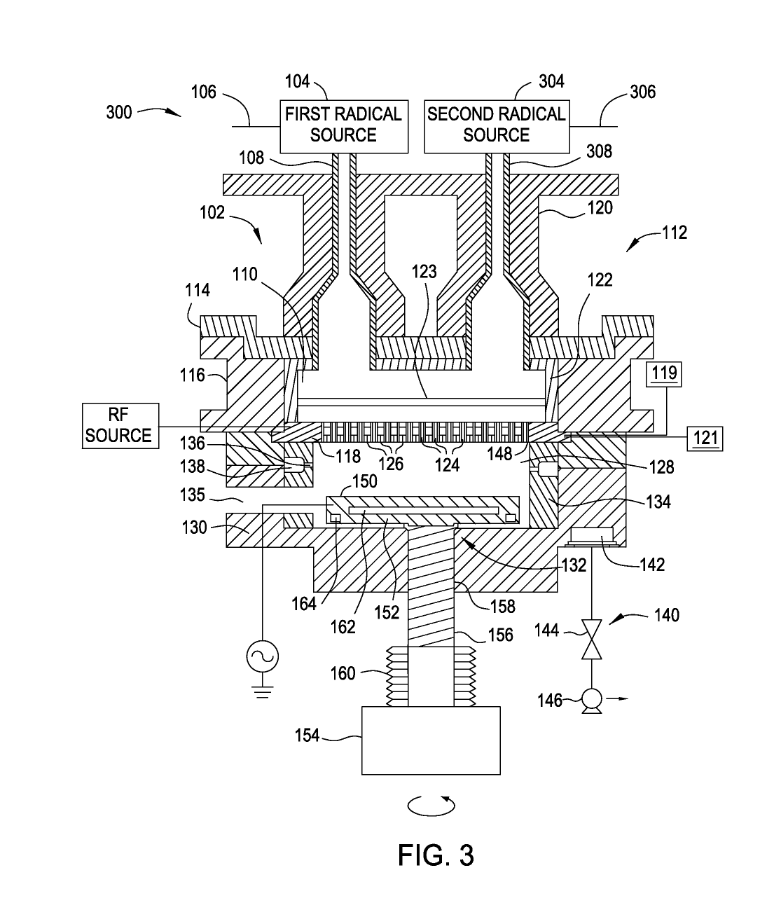

In some embodiments, a chamber may comprise more than one radical source. FIG. 3 is a cross sectional view of an apparatus 300 for radical-based forming and exposing of dielectric films. As shown in FIG. 3, the apparatus 300 is substantially similar to the apparatus 100 of FIG. 1 with the exception that the apparatus 300 comprises a second radical source 304 positioned adjacent to radical source 104. Two or more radical sources coupled with a chamber increases overall throughput by allowing, for example, a silicon-precursor plasma or argon-oxygen based plasma to form in one radical source and a hydrogen-radical based plasma to be formed in the second radical source. As shown in FIG. 3, the apparatus 300 includes a processing chamber 102 and radical sources 104 and 304 coupled with body 130. The radical sources 104 and 304 may be any suitable sources capable of generating radicals. The radical sources 104 and 304 may be the same type of radical source, or different kinds. Radical sources 104 and 304 may be a remote plasma source, such as a radio frequency (RF) or very high radio frequency (VHRF) capacitively coupled plasma (CCP) source, an inductively coupled plasma (ICP) source, a microwave induced (MW) plasma source, a DC glow discharge source, an electron cyclotron resonance (ECR) chamber, or a high density plasma (HDP) chamber. Alternatively, each of the radical sources 104 and 304 may be an ultraviolet (UV) source or the filament of a hot wire chemical vapor deposition (HW-CVD) chamber. The radical source 304 may include one or more gas inlets 306 and the radical source 304 may be coupled with the processing chamber 102 by a radical conduit 308. One or more process gases, which may be radical-forming gases, may enter the radical source 304 via the one or more gas inlets 306. The one or more process gases may comprise a hydrogen containing gas, such as hydrogen, H₂O, or ammonia. The one or more process gases may comprise oxygen, argon, or silicon-based gas. Radicals, such as hydrogen radicals, generated in the radical source 304 travel into the processing chamber 102 through the radical conduit 308. The radical conduit 308 is a part of a lid assembly 112. Radical conduit 308 may comprise a coating as described previously for radical conduit 108.

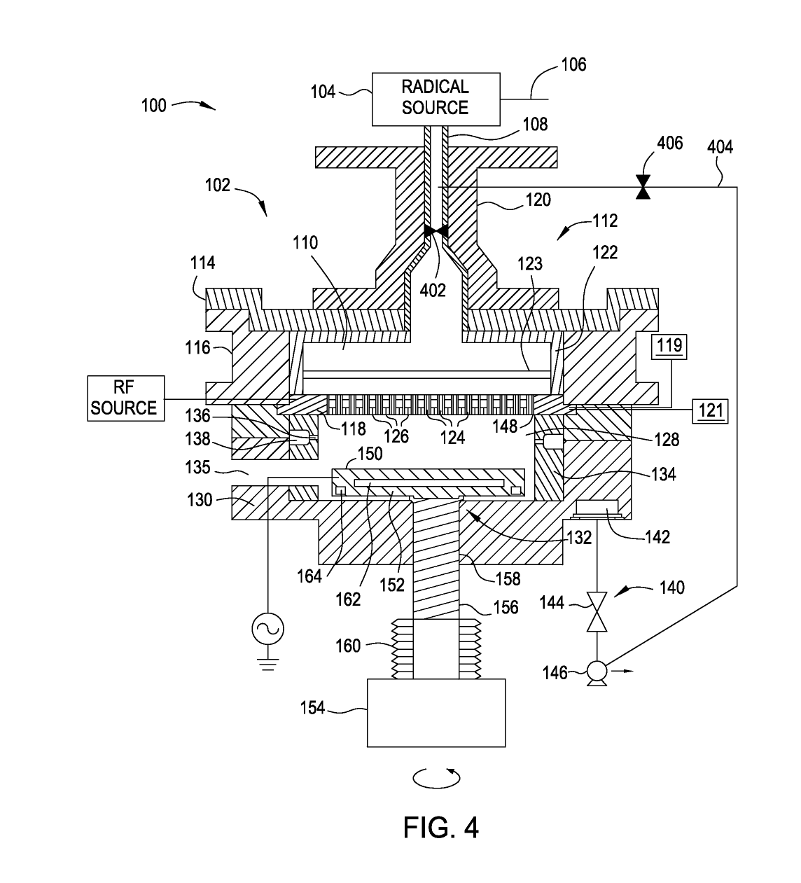

During an exposing process, the amount of radicals within one or more of the radical sources 104 and 304 may decrease over time. As such, it may be desirable to stop the exposing process and condition one or more of the radical sources with a conditioning gas. Conditioning gas may comprise any gas capable of conditioning a remote plasma source, such as radical sources 104 and/or 304. Conditioning gas may comprise oxygen and/or argon. When a substrate is present in the chamber 102 during conditioning, the substrate may undesirably undergo oxidation if oxygen is present in the conditioning gas. Oxidation of the substrate may be avoided by removing the substrate from the chamber 102 before conditioning one or more of the radical sources 104 and 304, followed by reentering the substrate into chamber 102 after the conditioning is completed. However, removing the substrate from the chamber 102 for conditioning of a radical source will slow overall throughput of film formation. Alternatively, a conditioning gas may be blocked from entering radical cavity 110 during conditioning of a radical source. FIG. 4 is a cross sectional view of an apparatus 400 for radical-based forming and exposing of dielectric films. As shown in FIG. 4, the apparatus 400 is substantially similar to the apparatus 100 of FIG. 1 with the exception that radical conduit 108 comprises valve 402, and radical source 104 and radical conduit 108 are in fluid communication with vacuum pump 146 by bypass 404 comprising valve 406. During conditioning of radical source 104, valve 402 is in a closed position and blocks a conditioning gas from entering radical cavity 110. Valve 406 is in an open position and allows fluid communication of radical source 104 with vacuum pump 146. Vacuum pump 146 evacuates conditioning gas from radical source 104 before, during or after conditioning of radical source 104. During a forming and/or exposing process, valve 402 is in an open position and allows fluid communication between radical source 104 and radical cavity 110. Valve 406 is in a closed position and blocks fluid communication of radical source 104 with vacuum pump 146 via bypass 404. Optionally, radical conduit 108 further comprises a second valve (not shown) located upstream from bypass 404. The second valve of radical conduit 108 prevents fluid communication of radical source 104 with each of chamber 102 and bypass 404 because the second valve is located upstream on radical conduit 108 relative to bypass 404.

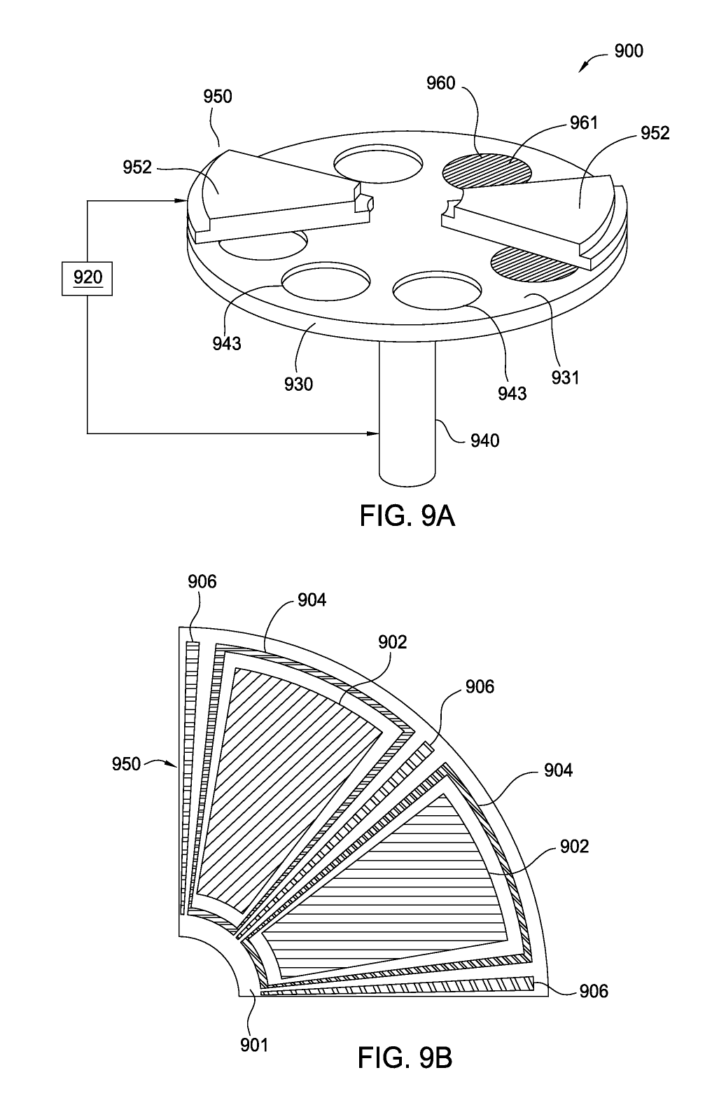

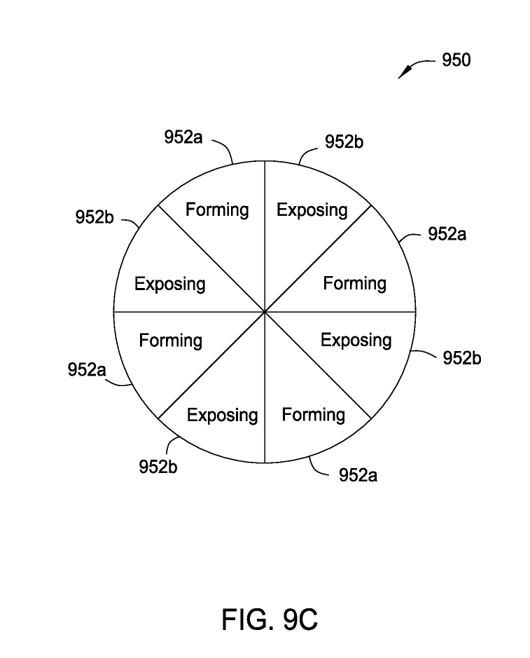

In some embodiments, forming and exposing processes may be performed by a carousel process. FIG. 9a is a perspective view of a carousel process chamber 900 capable of performing forming and exposing processes. The process chamber 900 may include a susceptor assembly 930 and a gas/plasma distribution assembly 950. The susceptor assembly 930 has a top surface 931 and a plurality of recesses 943 formed in the top surface 931. Each recess 943 may support one substrate 960. In some embodiments, the susceptor assembly 930 has six recesses for supporting six substrates 960. Each recess 943 is sized so that the substrate 960 supported in the recess 943 has the top surface 961 that is substantially coplanar with the top surface 931 of the susceptor assembly 930. The susceptor 930 may be rotated by a support shaft 940 during or between deposition/etching processes.

The gas/plasma distribution assembly 950 includes a plurality of pie-shaped sections 952. Portions of the gas/plasma distribution assembly 950 are removed to show the susceptor assembly 930 disposed below. Instead of being formed by the plurality of sections 952, the gas/plasma distribution assembly 950 may be formed in one piece having the same shape as the susceptor assembly 930.

The process chamber 900 further includes a controller 920. In some embodiments, the controller 920 may be loaded with programs when operated to perform methods according to embodiments of the present disclosure.

FIG. 9b is a schematic bottom view of a portion of the gas/plasma distribution assembly 950. The gas/plasma distribution assembly 950 has a surface 901 facing the susceptor assembly 930. A plurality of gas/plasma ports 902 may be formed in the surface 901. Surrounding each gas/plasma port 902 is a purge gas port 906. A vacuum port 906 may be positioned between adjacent gas/plasma ports 902. Each gas/plasma port 902 may be configured to deliver one or more process gases to perform deposition, etch, thermal process, surface treatment, a chamber treatment, or any process dictated of the process recipe to be performed.

During operation, the substrates 960 rotate relative to the gas/plasma distribution assembly 950 so that each substrate 960 sequentially faces the plurality of sections 952 to be processed by the plurality of sections 952. In one embodiment, two or more sections 952 configured for two or more processes may be activated at the same time so that the two or more processes are performed to the substrates 960 during each rotation. In another embodiment, only sections 952 configured to perform the same process are activated at any given time so that only one process is performed in the process chamber 900 at any given time and length of each process is controlled by the number of rotations during the process.

FIG. 9c is a schematic plan view of the gas/plasma distribution assembly 950 of FIG. 9b arranged according to one embodiment of the present disclosure. As shown in FIG. 9c, the gas/plasma assembly 950 may include eight gas/plasma ports 902 disposed across the surface 901. The gas/plasma assembly 950 may include eight sections 952 each having one gas/plasma port 902. In the configuration of FIG. 9c, the gas/plasma distribution assembly 950 includes four forming (e.g., deposition) sections 952a configured to deliver precursors for the forming process. The gas/plasma distribution assembly 950 may further include four exposing (e.g., curing) sections 952b configured to deliver, for example, hydrogen radicals. The distribution assembly 950 allows for improved throughput of, for example, dielectric films of a desired thickness where formation of the desired dielectric films with reduced hydrogen content comprises multiple forming and exposing processes.

Apparatus for reducing hydrogen content of a film may have a chamber body, a support member coupled to a lift mechanism, and a source of hydrogen radicals. The chamber may have a radical conduit coupled with the source of hydrogen radicals at a first end and coupled with the chamber body at a second end. The chamber may have a dual-channel showerhead coupled with a lid rim. The dual-channel showerhead may be disposed between the radical source and the support member. The showerhead may face the support member. Methods of reducing hydrogen content of a film may include forming a first film having a hydrogen content of about 1% to about 50% on a substrate in a chamber, and exposing the first film to hydrogen radicals to form a second film having reduced hydrogen content.

Apparatus and methods disclosed herein offer advantages, such as the following. The use of a radical source produces growth conditions that are substantially or completely free of film-damaging effects, such as charged-particle bombardment and high-energy ultraviolet irradiation, which often occur in conventional techniques and which next generation devices are particularly susceptible to. Additionally, the generated radicals during forming as well as during exposing abstract hydrogen from the Si—H, C—H, and N—H bonds of the precursors and/or deposited film, allowing for, at a given temperature, the forming and/or exposing of films having a lower hydrogen content than conventional techniques. The lower hydrogen content improves etch rate and electrical properties of a hydrogen radical treated film. Furthermore, silicon-containing dielectric films formed using the methods disclosed herein exhibit, as compared to currently used methods of forming silicon-containing dielectric films, fewer defects, lower shrinkage, better etch selectivity, mechanical stability, and thermal stability. Moreover, films deposited and exposed according to the methods disclosed herein offer greater conformality than, for example, conventional plasma enhanced chemical vapor deposition (PECVD) techniques. However, methods and apparatus of the present disclosure may still comprise PECVD methodology and apparatus. The aforementioned advantages are illustrative and not limiting. It is not necessary for all embodiments of the present disclosure to have all the advantages of the present disclosure or fulfill all the purposes of the present disclosure.

While the foregoing is directed to embodiments of the present disclosure, other and further embodiments of the present disclosure may be devised without departing from the basic scope thereof.

1. A method of reducing hydrogen content of a film, comprising:
forming a first film having a hydrogen content of about 1% to about 50% on a substrate in a chamber; and
exposing the first film to hydrogen radicals to form a second film having reduced hydrogen content.

2. The method of claim 1, wherein the hydrogen radicals are formed from H₂ gas in a remote plasma source.

3. The method of claim 1, further comprising:
forming a third film having a hydrogen content of about 1% to about 50%, wherein the third film is deposited onto the second film; and
exposing the third film with hydrogen radicals to form a fourth film having reduced hydrogen content.

4. The method of claim 1, further comprising conditioning a radical source coupled to the chamber with a conditioning gas selected from the group consisting of argon and oxygen, wherein the radical source is used to generate hydrogen radicals.

5. The method of claim 1, wherein the forming and the exposing are performed in the chamber.

6. The method of claim 1, wherein the chamber is a carousel chamber, and the forming and the exposing are performed in the carousel chamber.

7. The method of claim 1, wherein the forming is performed using a dual-channel showerhead.

8. The method of claim 1, wherein the first film is a dielectric film selected from the group consisting of SiO₂, SiN, SiC, SiO, SiCN, SiOC, SiON and SiCON.

9. The method of claim 1, wherein the exposing is performed in a chamber comprising a radical source and radical conduit, wherein the radical source and the radical conduit are in fluid communication with a vacuum pump via a bypass.

10. The method of claim 1, wherein exposing the first film with hydrogen radicals is performed using a remote plasma source.

11. The method of claim 1, wherein the first film has a thickness less than about 20 Å.

12. The method of claim 11, wherein the first film has a thickness of about 1 Å.

13. The method of claim 1, wherein the second film has a hydrogen content of about 15%.

14. An apparatus for reducing hydrogen content of a film, comprising:
a chamber body;
a support member coupled with a lift mechanism;
a source of hydrogen radicals coupled with a radical conduit, wherein the radical conduit is coupled with the source of hydrogen radicals at a first end and coupled with the chamber body at a second end; and
a dual-channel showerhead coupled with a lid rim, wherein the dual-channel showerhead is disposed between the radical source and the support member, wherein the showerhead faces the support member.

15. The apparatus of claim 14, further comprising a radical distribution plate coupled with the lid rim, wherein the radical distribution plate faces the showerhead.

16. The apparatus of claim 14, further comprising a second radical source and a second radical conduit, wherein the second radical conduit is coupled with the second radical source at a first end and coupled with the chamber body at a second end.

17. The apparatus of claim 14, wherein the radical source and the radical conduit are in fluid communication with a vacuum pump via a bypass, wherein the bypass is coupled with the radical conduit at a first end and coupled with the vacuum pump at a second end.

18. The apparatus of claim 14, wherein one or more of the chamber body, the dual-channel showerhead and the radical conduit comprises a coating selected from the group consisting of AlN, SiO₂, Y₂O₃, MgO, anodized Al₂O₃, sapphire, and ceramic containing one or more of Al₂O₃, sapphire, AlN, Y₂O₃, MgO, or plastic.

19. The apparatus of claim 14, wherein the lift mechanism comprises a rotor coupled to the support member.

20. The apparatus of claim 16, wherein the second radical source and the second radical conduit are in fluid communication with a vacuum pump via a bypass, wherein the bypass is coupled with the second radical conduit at a first end and coupled with the vacuum pump at a second end.
